(19) United States
(12) Patent Application Publication
(10) Pub. No.: US 2025/0279286 A1
(43) Pub. Date: Sep. 4, 2025

(54) METHOD OF MANUFACTURING SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Hiroki MIYAKE, Nisshin-shi (JP); Shuhei ICHIKAWA, Nisshin-shi (JP); Yoshitaka NAGASATO, Nisshin-shi (JP)

(21) Appl. No.: 18/955,262

(22) Filed: Nov. 21, 2024

(30) Foreign Application Priority Data
Feb. 29, 2024 (JP) 2024-030235

(51) Int. Cl. H01L 21/425; H01L 21/477

(52) U.S. Cl. CPC H01L 21/425; H01L 21/477

(57) ABSTRACT

A method of manufacturing a semiconductor device includes: preparing a semiconductor substrate made of an oxide semiconductor; ion-implanting impurities of a first conductivity type or a second conductivity type into the semiconductor substrate; performing an oxygen vacancy compensation within a region of the semiconductor substrate in which an ion implantation layer is to be formed; and performing a heating process to activate the impurities and form the ion implantation layer.

### CROSS REFERENCE TO RELATED APPLICATION

This application is based on Japanese Patent Application No. 2024-030235 filed on Feb. 29, 2024, the disclosure of which is incorporated herein by reference.

### TECHNICAL FIELD

The present disclosure relates to a method of manufacturing a semiconductor device having a semiconductor substrate made of an oxide semiconductor.

### BACKGROUND

A semiconductor device has a semiconductor substrate made of an oxide semiconductor. For example, as a semiconductor device, a Schottky barrier diode is configured using a semiconductor substrate made of an oxide semiconductor. Specifically, the semiconductor device has a semiconductor substrate formed by stacking an n− type semiconductor on an n+ type substrate. The semiconductor device has a first electrode that is Schottky-connected to the semiconductor layer, and a second electrode that is ohmic-connected to the substrate. In this semiconductor device, a guard ring layer is formed as an electric field concentration alleviation structure on the outer periphery of the semiconductor layer that is connected to the first electrode.

### SUMMARY

According to one aspect of the present disclosure, a method of manufacturing a semiconductor device includes: preparing a semiconductor substrate made of an oxide semiconductor; ion-implanting an impurity of a first conductivity type or a second conductivity type on one surface of the semiconductor substrate; compensating for an oxygen vacancy within a region of the semiconductor substrate to form an ion implantation layer before heating; and performing a heat treatment to activate the impurity and form an ion implantation layer after heating.

### BRIEF DESCRIPTION OF DRAWINGS

FIG. 1 is a cross-sectional view of a semiconductor device according to a first embodiment.

FIG. 2A is a cross-sectional view illustrating a manufacturing step of the semiconductor device of FIG. 1.

FIG. 2B is a cross-sectional view illustrating a manufacturing step of the semiconductor device, subsequent to the step shown in FIG. 2A.

FIG. 2C is a cross-sectional view illustrating a manufacturing step of the semiconductor device, subsequent to the step shown in FIG. 2B.

FIG. 2D is a cross-sectional view illustrating a manufacturing step of the semiconductor device, subsequent to the step shown in FIG. 2C.

FIG. 3 is a graph showing Mg concentration and O concentration before heat treatment, taken along a line A-A in FIG. 5.

FIG. 4 is a graph showing Mg concentration and the O concentration after heat treatment, taken along a line A-A in FIG. 5.

FIG. 5 is a cross-sectional view showing a semiconductor substrate used in the experiments of FIGS. 3 and 4.

FIG. 6 is a graph showing Mg concentration and O concentration before heat treatment, taken along a line A-A in FIG. 5.

FIG. 7 is a graph showing Mg concentration and O concentration after heat treatment, taken along a line A-A in FIG. 5.

FIG. 8 is a diagram showing a relationship between a ratio of O concentration to Mg concentration and a Mg termination depth.

FIG. 9 is a diagram for explaining a relationship between a depth and Mg concentration and O concentration.

FIG. 10 is a diagram for explaining a relationship between a depth and Mg concentration and O concentration.

FIG. 11 is a diagram for explaining a relationship between a depth and Mg concentration and O concentration.

FIG. 12 is a diagram for explaining a relationship between a depth and Mg concentration and O concentration.

FIG. 13 is a diagram showing a relationship between a before-heating ion implantation layer and an oxygen ion implantation layer.

FIG. 14 is a cross-sectional view of a semiconductor device according to a modification of the first embodiment.

FIG. 15 is a cross-sectional view of a semiconductor device according to a second embodiment.

### DETAILED DESCRIPTION

A semiconductor device has a semiconductor substrate made of an oxide semiconductor. For example, as a semiconductor device, a Schottky barrier diode is configured using a semiconductor substrate made of an oxide semiconductor. Specifically, the semiconductor device has a semiconductor substrate formed by stacking an n− type semiconductor on an n+ type substrate. The semiconductor device has a first electrode that is Schottky-connected to the semiconductor layer, and a second electrode that is ohmic-connected to the substrate. In this semiconductor device, a guard ring layer is formed as an electric field concentration alleviation structure on the outer periphery of the semiconductor layer that is connected to the first electrode.

The guard ring layer is formed by ion-implanting p-type impurities into a semiconductor layer and then performing a heat treatment to activate the p-type impurities. That is, the guard ring layer is formed by the ion implantation layer after heating.

However, the inventors have found through their investigations that the desired characteristics cannot be obtained due to diffusion of the impurities when an ion-implantation layer after heating, such as a guard ring layer, is formed on a semiconductor substrate made of an oxide semiconductor. For example, when a guard ring layer is formed in the Schottky barrier diode as described above, if the guard ring layer is formed to extend beyond a desired range, it may not be possible to obtain the desired electric field relaxation function.

The present disclosure provides a method of manufacturing a semiconductor device so as to suppress diffusion of an ion implantation layer after heating.

According to one aspect of the present disclosure, a method of manufacturing a semiconductor device includes: preparing a semiconductor substrate made of an oxide semiconductor; ion-implanting an impurity of a first conductivity type or a second conductivity type from one surface of the semiconductor substrate; compensating for an oxygen vacancy within a region of the semiconductor substrate in which an ion implantation layer is to be formed after heating; and performing a heat treatment to activate the impurity and form the ion implantation layer.

Accordingly, the oxygen vacancy is compensated within the region in which the ion implantation layer is to be formed after heating. Therefore, the impurity of the ion implantation layer after heating can be restricted from diffusing through the oxygen vacancy, so that fluctuations in the characteristics of the semiconductor device can be suppressed.

Hereinafter, embodiments of the present disclosure will be described with reference to the drawings. In the following embodiments, the same or equivalent parts are denoted by the same reference numerals as each other, and explanations will be provided to the same reference numerals.

### First Embodiment

A first embodiment will be described with reference to the drawings. In the first embodiment, a semiconductor device has a Schottky barrier diode including an ion implantation layer. A configuration of the semiconductor device in the present embodiment will be described.

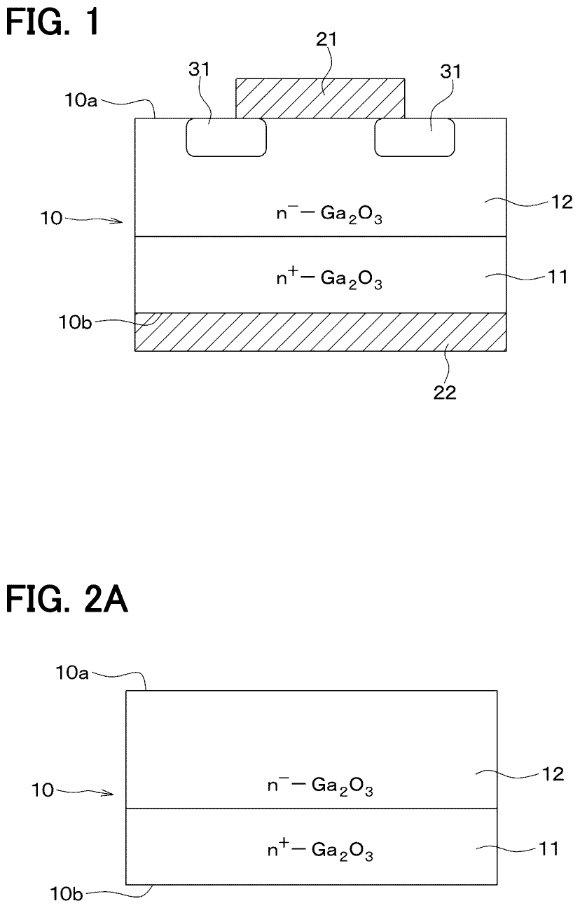

As shown in FIG. 1, the semiconductor device includes a semiconductor substrate 10 made of an oxide semiconductor. The semiconductor substrate 10 of this embodiment includes an n+ type substrate 11 made of Ga₂O₃ (i.e., gallium oxide) doped with Sn (i.e., tin), and an n− type semiconductor layer 12 made of Ga₂O₃ and disposed on the substrate 11. In this embodiment, the semiconductor layer 12 is composed of an epitaxial layer grown on the substrate 11. Hereinafter, in the semiconductor substrate 10, a surface of the semiconductor layer 12 opposite to the substrate 11 is referred to as one surface 10a of the semiconductor substrate 10, and a surface of the substrate 11 opposite to the semiconductor layer 12 is referred to as the other surface 10b of the semiconductor substrate 10.

A first electrode 21 that is Schottky-connected to the semiconductor layer 12 is disposed on the one surface 10a of the semiconductor substrate 10. A second electrode 22 that is ohmic-connected to the substrate 11 is disposed on the other surface 10b of the semiconductor substrate 10.

A guard ring layer 31 formed by activating p-type impurities is arranged on the outer periphery of the semiconductor layer 12 connected to the first electrode 21. The guard ring layer 31 constitutes an electric field concentration alleviation structure that suppresses the electric field concentration on the outer periphery where the first electrode 21 and the semiconductor layer 12 are connected. As will be described later, the guard ring layer 31 is formed by ion-implanting p-type impurities and then activating the p-type impurities by heat treatment. In this embodiment, the guard ring layer 31 corresponds to an ion implantation layer after heating.

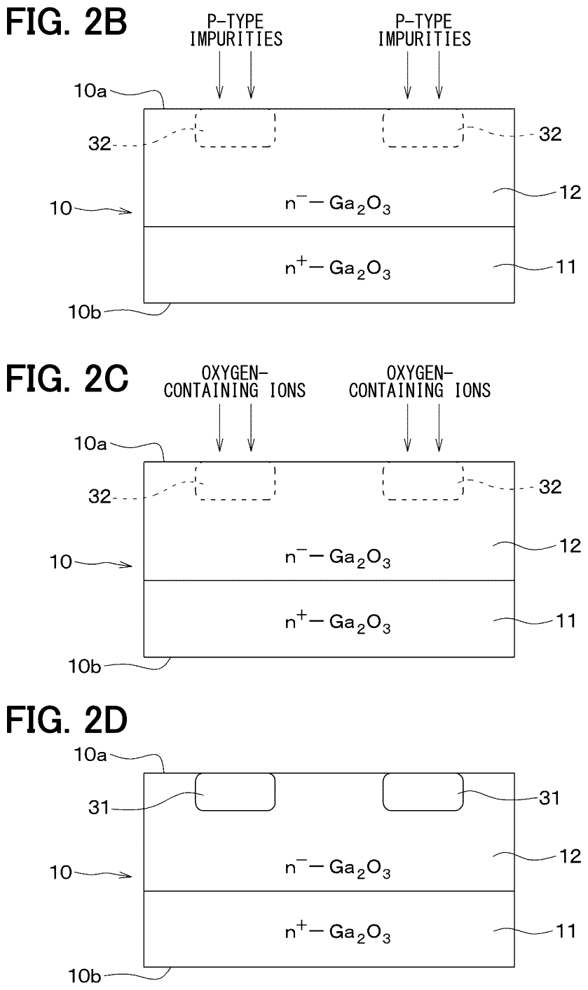

In this embodiment, the n-type can also be referred to as a first conductivity type, and the p-type can also be referred to as a second conductivity type. Next, a method of manufacturing the semiconductor device will be described with reference to FIGS. 2A to 2D.

First, as shown in FIG. 2A, a semiconductor substrate 10 is prepared, in which a semiconductor layer 12 is arranged on a substrate 11.

Next, as shown in FIG. 2B, a mask (not shown) having an opening corresponding to the region where the guard ring layer 31 is to be formed is placed on the semiconductor layer 12, and an ion implantation layer 32 before heating is formed by ion-implanting p-type impurities. The p-type impurity is, for example, Mg (magnesium), Be (beryllium), Ca (calcium), Zn (zinc), N (nitrogen), Ni (nickel), Cu (copper), or the like. The ion implantation is performed, for example, at a temperature of 500° C. When the impurity is ion-implanted at a temperature of 500° C. or less, the impurity is in an inactive state, that is, not activated. Therefore, in this step, the ion implantation layer 32 in which the impurities are not activated is formed.

The guard ring layer 31 shown in FIG. 1 is formed by ion-implanting p-type impurities and then activating the p-type impurities by carrying out a heat treatment. However, when activating the p-type impurities, there is a possibility that the p-type impurities will diffuse. If the guard ring layer 31 is formed in a state where the p-type impurity has been diffused excessively, the characteristics of the guard ring layer 31 may change, which may result in changes in the characteristics of the semiconductor device. For this reason, the present inventors have conducted extensive research into the diffusion of p-type impurities when forming the guard ring layer 31. The present inventors have presumed that the diffusion of p-type impurities occurs via oxygen vacancies contained in the oxide semiconductor (i.e., Ga₂O₃), as will be described later in detail.

In this embodiment, after the p-type impurity ions are implanted, as shown in FIG. 2C, an oxygen vacancy compensation step is performed to compensate for oxygen vacancies in the region including the ion implantation layer 32. That is, the oxygen vacancy compensation step is performed to compensate for oxygen vacancies in the region where the guard ring layer 31 is to be formed. In this embodiment, the oxygen vacancy compensation step is performed by implanting oxygen ions as oxygen-containing ions into the region including the ion implantation layer 32. That is, in this embodiment, an oxygen vacancy compensation step is performed in which oxygen ions are implanted to reduce oxygen vacancies in the ion implantation layer 32. Examples of the oxygen-containing ion include O, CO₂, ¹⁸O, and MgO. Moreover, the formation of the ion implantation layer 32 and the implantation of oxygen ions may be performed in any order.

Then, as shown in FIG. 2D, a heat treatment is performed at a temperature of 1000° C. or higher to sufficiently activate the p-type impurity, thereby forming the guard ring layer 31. After that, although not shown, the first electrode 21 and the second electrode 22 are formed, thereby completing the manufacture of the semiconductor device. The heat treatment for forming the guard ring layer 31 may be performed in common with a heat treatment performed in a separate subsequent step.

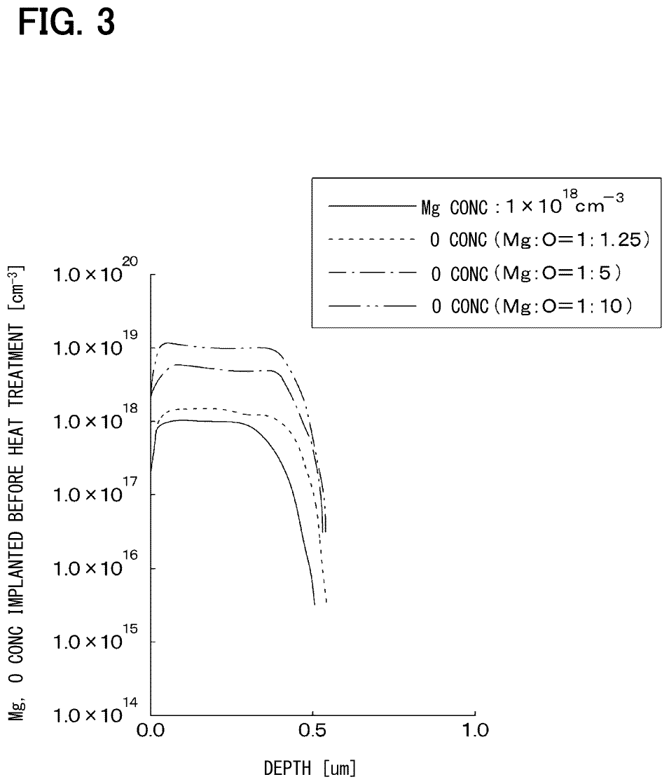

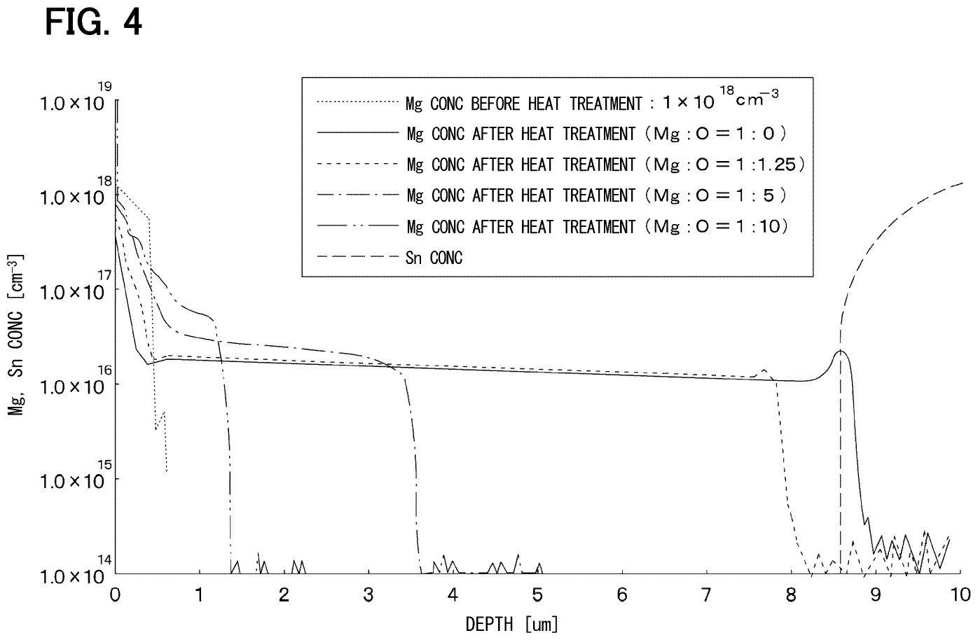

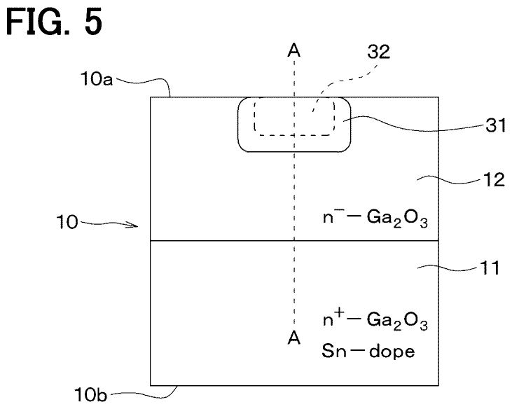

Next, the relationship between the oxygen ions and the diffusion of p-type impurities will be described. The present inventors have conducted extensive research into the relationship between the oxygen ions and the diffusion of p-type impurities, and have obtained the results shown in FIGS. 3 and 4. FIGS. 3 and 4 show the relationship between the concentration and the depth along a line A-A in FIG. 5 in which the ion implantation layer 32 is formed and then a heating process is performed to form the guard ring layer 31. In FIG. 5, only one guard ring layer 31 is shown for simplicity. The ion implantation layer 32 before heating is formed by ion-implanting Mg as a p-type impurity, and oxygen ions are implanted into a region including the ion implantation layer 32. Each ion implantation is carried out at 500° C., and the heat treatment is carried out at 1000° C. or higher.

In FIGS. 3 and 4, a depth represents a dimension in a depth direction from the one surface 10a of the semiconductor substrate 10 toward the other surface 10b of the semiconductor substrate 10, and the thickness of the semiconductor layer 12 is 8.5 μm. Therefore, a depth of 0 μm in FIGS. 3 and 4 refers to the one surface 10a of the semiconductor substrate 10. The Mg concentration before heat treatment in FIG. 4 is the same as the Mg concentration in FIG. 3. The Sn concentration in FIG. 4 indicates the concentration of Sn doped in the substrate 11.

FIG. 3 shows the results when Mg is ion-implanted so that the Mg concentration in the ion implantation layer 32 before heating is 1×10¹⁸ cm⁻³, and the depth of the ion implantation layer 32 is about 0.5 μm. FIG. 3 shows the results of O concentration (that is, oxygen concentration) when oxygen ions are implanted at different concentrations to approximately the same depth as the ion implantation layer 32. Specifically, in FIG. 3, oxygen ions are implanted so that the O concentration becomes 1.25×10¹⁸ cm⁻³, 5×10¹⁸ cm⁻³, or 1×10¹⁹ cm⁻³. In FIGS. 3 and 4, the O concentration is set as a ratio of the O concentration to the Mg concentration of 1:1.25 when the O concentration is 1.25×10 cm, 1:5 when the O concentration is 5×10¹⁸ cm⁻³, and 1:10 when the O concentration is 1×10¹⁹ cm⁻³. In FIG. 4, as a comparative example, the ratio of Mg concentration to O concentration is shown as 1:0 where no oxygen ions are implanted. In the case of implanting oxygen ions, CO₂ gas is subjected to mass separation, and the extracted oxygen ions are implanted.

As shown in FIG. 4, when the guard ring layer 31 is formed, in the case where oxygen ions are not implanted (i.e., Mg:O=1:0), it is confirmed that Mg is widely diffused in the depth direction compared to the Mg before the heat treatment. In this example, it is confirmed that Mg is diffused to a depth of 8.5 μm, that is, the interface with the substrate 11.

It is confirmed that the Mg termination depth becomes shallower by implanting oxygen ions. In other words, it is confirmed that Mg becomes less likely to diffuse by compensating for oxygen vacancies. In this example, it is confirmed that the greater the amount of oxygen ions implanted, the shallower the Mg termination depth becomes. In other words, it is confirmed that the greater the ratio of the O concentration to the Mg concentration, the shallower the Mg termination depth becomes.

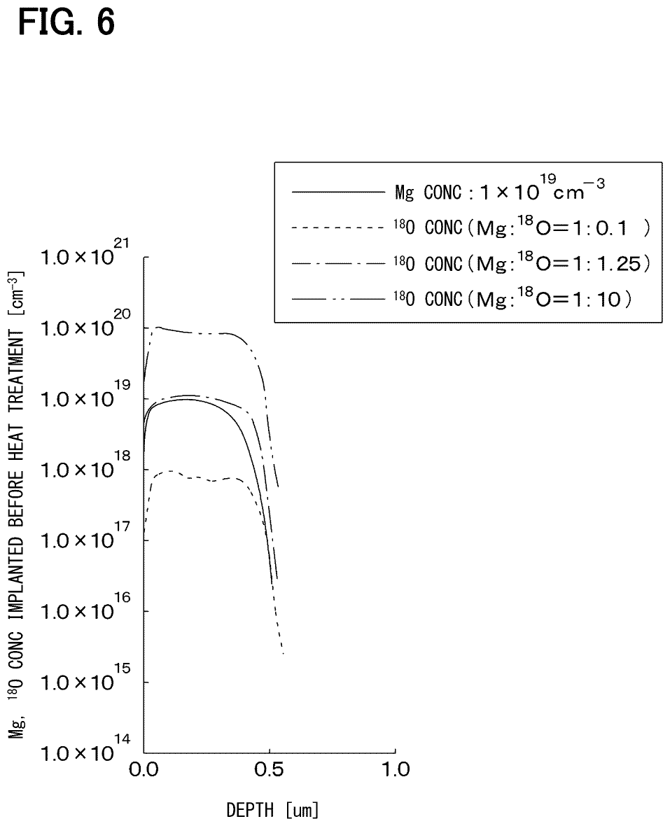

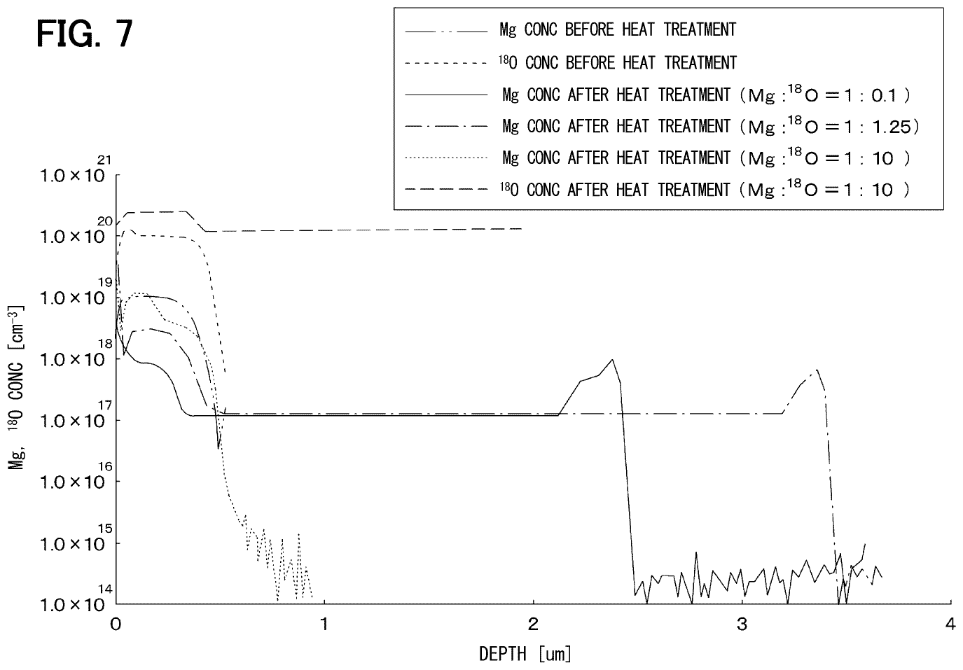

The present inventors also carried out similar experiments by changing the Mg concentration, and obtained the results shown in FIGS. 6 and 7. FIG. 6 shows the result of Mg ion implantation so that the Mg concentration becomes 1×10¹⁹ cm⁻³, and the depth of the ion implantation layer 32 is set to about 0.5 μm. FIG. 6 shows the result of implanting oxygen ions with varying concentrations to approximately the same depth as the ion implantation layer 32. Specifically, in FIG. 6, oxygen ions are implanted so that the ¹⁸O concentration becomes 1×10¹⁸ cm⁻³, 1.25×10¹⁹ cm⁻³, or 1×10²⁰ cm⁻³. In FIGS. 6 and 7, the ratio of the ¹⁸O concentration to the Mg concentration is shown as 1:0.1 when the ¹⁸O concentration is 1×10¹⁸ cm⁻³, as 1:1.25 when the ¹⁸O concentration is 1.25×10¹⁹ cm⁻³, and as 1:10 when the ¹⁸O concentration is 1×10²⁰ cm⁻³. In the case of implanting oxygen ions, ¹⁸O (that is, oxygen isotope) is implanted as oxygen-containing ions.

The Mg concentration before heat treatment in FIG. 7 is the same as the Mg concentration in FIG. 6. The ¹⁸O concentration before heat treatment in FIG. 7 is the same as that in FIG. 6 when the ¹⁸O concentration before heat treatment is 1×10²⁰ cm⁻³ (that is, Mg:¹⁸O=1:10). The ¹⁸O concentration after heat treatment in FIG. 7 represents the entire ¹⁸O concentration contained in the semiconductor substrate 10.

As shown in FIG. 7, when the guard ring layer 31 is formed, it is confirmed that the diffusion of Mg is suppressed when the ratio of Mg concentration to ¹⁸O concentration is 1:0.1, compared to a case where oxygen ions are not implanted in FIG. 4 (i.e., Mg:¹⁸O=1:0). In other words, it is confirmed that the diffusion of Mg can be suppressed by implanting oxygen ions, and that the diffusion of Mg can be sufficiently suppressed if the ¹⁸O concentration is at least 0.1 times the Mg concentration.

In this example, it is confirmed that Mg and O hardly diffuse when the ratio of the Mg concentration to the ¹⁸O concentration is 1:10. The ¹⁸O concentration after heat treatment is the overall ¹⁸O concentration contained in the semiconductor substrate 10. In the range of a depth of about 0.5 μm or less, the ¹⁸O concentration is higher by the amount of the oxygen isotopes, than at locations deeper than 0.5 μm, because the ion-implanted oxygen isotopes are included.

Furthermore, the results in FIG. 7 confirm that Mg diffuses less when the ratio of Mg concentration to ¹⁸O concentration is 1:0.1 than when the ratio of Mg concentration to ¹⁸O concentration is 1:1.25. Although the reason for this is not clear, the inventors presume that the relationship between the amount of Mg implanted and the amount of oxygen isotopes (i.e., oxygen ions) implanted is due to the influence of a relationship between the oxygen vacancies to be formed during the Mg ion implantation and the amount of compensation for the oxygen vacancies with the oxygen isotopes.

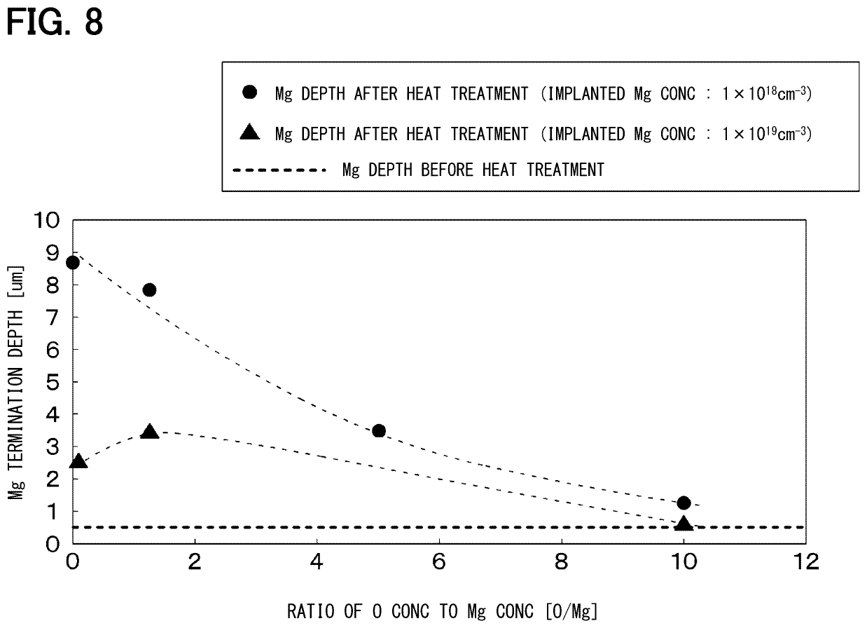

The relationship of FIG. 4 and FIG. 7 is summarized as shown in FIG. 8. As shown in FIG. 8, it is confirmed that within a range where the ratio of the O concentration to the Mg concentration (O/Mg) is greater than 1.25, the greater the O/Mg ratio, the more difficult it becomes for Mg to diffuse. The Mg depth before heat treatment in FIG. 8 is the Mg termination depth before heat treatment, and is about 0.5 μm in FIGS. 3 and 6.

To summarize the above results, the relationship between the Mg concentration and the O concentration may be as follows before the heat treatment when the oxygen vacancy compensation step is performed.

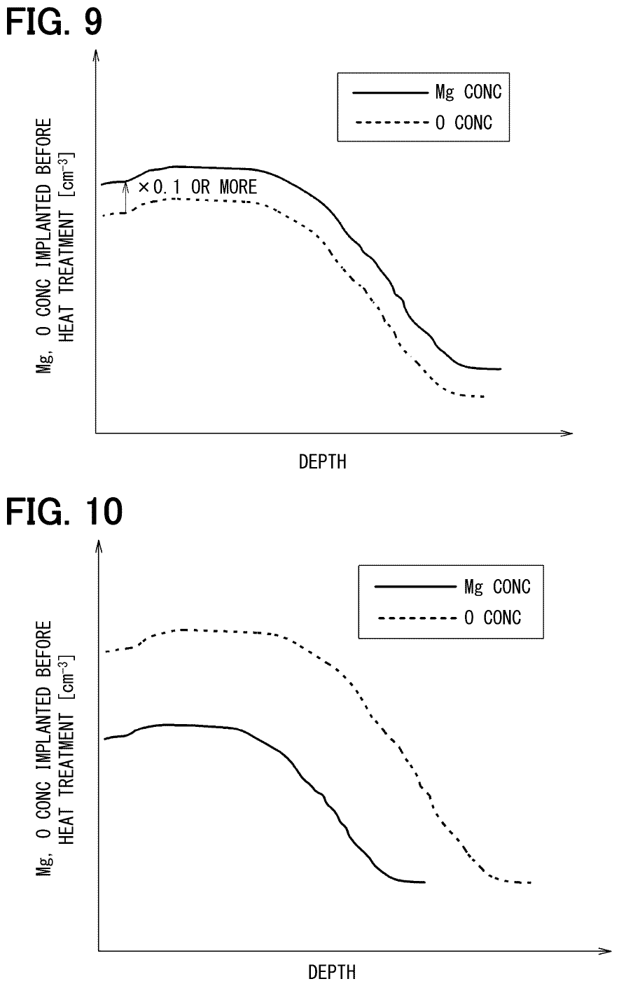

As shown in FIG. 9, when Mg is ion-implanted as a p-type impurity, it is preferable that the O concentration is more than or equal to 0.1 times the Mg concentration. This makes it possible to sufficiently suppress the diffusion of Mg. Although the above describes an example of implanting Mg ions as a p-type impurity, the same effect can be obtained by ion implanting other impurities, which will be described later, while the O concentration is 0.1 times or more the concentration of the implanted impurity.

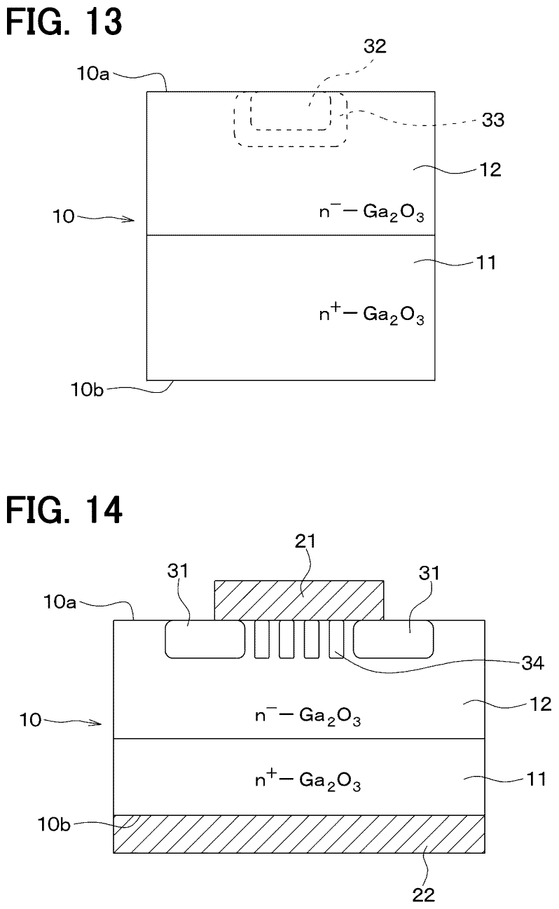

As described above, it is presumed that Mg is diffused through oxygen vacancies when activated by heat treatment. For this reason, as shown in FIGS. 10 to 12, it is preferable that oxygen ions are implanted deeper than the impurities for forming the guard ring layer 31. In other words, in the state before the heat treatment, it is preferable that the termination depth of the O concentration is made deeper than the termination depth of the Mg concentration. This makes it easier to suppress diffusion of Mg in the depth direction. In this case, as shown in FIG. 13, if the region into which oxygen ions are implanted is defined as an oxygen ion implantation layer 33, the oxygen ion implantation layer 33 is preferably formed so as to entirely surround the ion implantation layer 32. In other words, it is preferable that the ion implantation layer 32 exists only in the oxygen ion implantation layer 33. This also makes it possible to suppress diffusion of Mg in the surface direction of the semiconductor substrate 10.

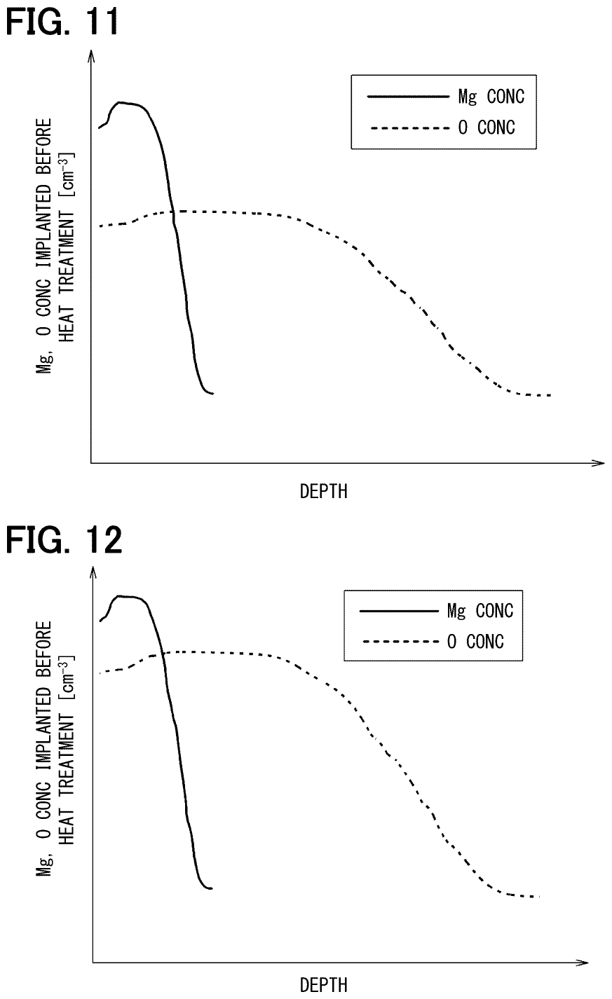

As shown in FIG. 10, the O concentration is preferably higher than the Mg concentration throughout the entire region in the depth direction. However, as shown in FIG. 11, even if the O concentration is partially lower than the Mg concentration, it is possible to suppress the diffusion of Mg by compensating for oxygen vacancies. As shown in FIG. 12, the total amount of oxygen ions to be implanted is preferably greater than the total amount of Mg ions to be implanted. This makes it easier to compensate for oxygen vacancies and suppress the diffusion of Mg.

In FIGS. 10 to 12, Mg is used as an example of the p-type impurity for forming the guard ring layer 31, but the same applies to the case where other p-type impurities are ion-implanted. Further, although the guard ring layer 31 is formed by ion implantation of p-type impurities, the same applies to the case in which an ion implantation layer is formed after heating by ion implantation of n-type impurities. For example, when impurities are ion-implanted into the semiconductor substrate 10 made of an oxide semiconductor to form an ion implantation layer after heating, examples of the impurities that may be used include at least one of Mg, Be, Ca, Zn, N, Ni, Cu, Si, Ge, Sn, C, and Cl.

According to the present embodiment, the oxygen vacancy compensation step is performed before the heat treatment to form the guard ring layer 31 (that is, an ion implantation layer after heating). This restricts impurities of the guard ring layer 31 from diffusing through oxygen vacancies, to reduce fluctuation in the characteristics of the semiconductor device.

Moreover, in this embodiment, the oxygen vacancy compensation step can suppress the diffusion of impurities. Therefore, when the impurities are activated by heat treatment, the heat treatment can be performed at a high temperature of 1000° C. or more, and the impurities can be sufficiently activated.
(1) In this embodiment, the oxygen vacancy compensation step is performed by implanting oxygen-containing ions. Therefore, oxygen vacancies can be compensated for in a simple manner.
(2) In this embodiment, the ion implantation layer after heating can be formed by ion-implanting at least one of Mg, Be, Ca, Zn, N, Ni, Cu, Si, Ge, Sn, C, and CI as an impurity for forming the ion implantation layer. This allows for greater freedom in the selection of impurities.
(3) In this embodiment, when the guard ring layer 31 is formed by Mg ion implantation, it is possible to sufficiently suppress diffusion of Mg during the heat treatment, by implanting oxygen-containing ions so that the O concentration before the heat treatment is 0.1 times or more the Mg concentration (i.e., the implanted impurity concentration).
(4) In this embodiment, the O concentration before the heat treatment is generally higher than the impurity concentration, which makes it easier to suppress the diffusion of impurities when the heat treatment is performed.
(5) In this embodiment, the termination depth of the oxygen-containing ions before the heat treatment is set to be deeper than the termination depth of the impurities, which makes it easier to suppress the diffusion of the impurities when the heat treatment is performed.
(6) In the present embodiment, the total amount of oxygen-containing ions is set to be greater than the total amount of impurities implanted when forming the ion implantation layer 32. This makes it easier to suppress diffusion of impurities during the heat treatment.

### Modification of First Embodiment

A modification of the first embodiment will be described below. As shown in FIG. 14, the semiconductor device may be configured so that a junction barrier Schottky diode forms a donor compensation layer 34 on the inner periphery of the semiconductor layer 12 that is connected to the first electrode 21. In this case, the donor compensation layer 34, like the guard ring layer 31, is composed of the ion implantation layer after heating in which p-type impurities are ion-implanted and then activated. Therefore, by performing the oxygen vacancy compensation step also on the portion where the donor compensation layer 34 is to be formed, it is possible to suppress diffusion of the donor compensation layer 34.

### Second Embodiment

A second embodiment will be described. In this embodiment, the semiconductor element is changed from that of the first embodiment. The remaining configurations are similar to those of the first embodiment and will thus not be described repeatedly.

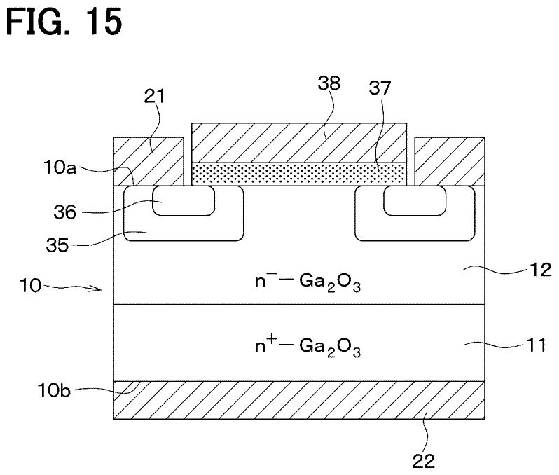

As shown in FIG. 15, the semiconductor device of this embodiment is configured by forming a MOSFET. Specifically, this semiconductor device includes a semiconductor substrate 10 similar to that of the first embodiment. A channel layer 35 serving as a donor compensation layer is formed on the one surface 10a of the semiconductor substrate 10. An n-type source layer 36 is formed on the surface portion of the channel layer 35.

The channel layer 35 is formed by ion-implanting p-type impurities and then activating the p-type impurities. The source layer 36 is formed by ion-implanting n-type impurities and then activating p-type impurities. Therefore, in this embodiment, the channel layer 35 and the source layer 36 correspond to an ion implantation layer after heating.

Moreover, a gate insulating film 37 made of an oxide film or the like is disposed on the one surface 10a of the semiconductor substrate 10, and located above the channel layer 35. A gate electrode 38 made of doped polysilicon or the like is disposed on the gate insulating film 37.

A first electrode 21 is disposed on the one surface 10a of the semiconductor substrate 10. The first electrode 21 is connected to the channel layer 35 and the source layer 36 to function as a source electrode. A second electrode 22 that is connected to the substrate 11 to function as a drain electrode is disposed on the other surface 10b of the semiconductor substrate 10.

Such a semiconductor device is manufactured by preparing the semiconductor substrate 10, and then forming the channel layer 35 and the source layer 36, as well as forming the gate insulating film 37, the gate electrode 38, the first electrode 21, the second electrode 22, and the like.

The channel layer 35 is formed by ion-implanting a p-type impurity and then activating the p-type impurity, and the source layer 36 is formed by ion-implanting an n-type impurity and then activating the n-type impurity. For this reason, in this embodiment, when forming the channel layer 35, p-type impurity ions are implanted and oxygen-containing ions are implanted, and then a heat treatment is performed to form the channel layer 35. Similarly, when forming the source layer 36, n-type impurity ions are implanted and oxygen-containing ions are implanted, and then heating is performed to form the channel layer 35. In this case, the step of implanting oxygen-containing ions when forming the channel layer 35 and the step of implanting oxygen-containing ions when forming the source layer 36 may be performed in the same step.

As in the present embodiment, a semiconductor device includes the channel layer 35 and the source layer 36 formed of the ion implantation layer after heating, and the oxygen vacancy compensation step can be performed to suppress diffusion of the impurities forming the channel layer 35 and the source layer 36. Other Embodiments

Although the present disclosure has been described in accordance with the embodiments, it is understood that the present disclosure is not limited to such embodiments or structures. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

In each of the embodiments, the heat treatment is performed at 1000° C. or higher. However, the heat treatment may be performed at a temperature lower than 1000° C. while the impurities are activated. For example, the heat treatment may be performed at a temperature higher than 500° C. and lower than 1000° C.

In each of the embodiments, the oxygen vacancy compensation step may be performed by a method other than implanting oxygen-containing ions. For example, before ion-implanting impurities into the semiconductor substrate 10, a heat treatment may be performed in the atmosphere to take in oxygen from the atmosphere into the semiconductor substrate 10, thereby compensating for oxygen vacancies.

Furthermore, in each of the embodiments, after the oxygen vacancy compensation step is performed, the ion implantation of impurities and the activation of the impurities by carrying out a heat treatment may be performed simultaneously. For example, after the oxygen vacancy compensation step, impurity ions may be implanted at a temperature of 1000° C., thereby activating the impurity while implanting the impurity ions. According to this, the heat treatment only for activating the impurities becomes unnecessary, and the number of manufacturing steps can be reduced.

In each of the embodiments, the semiconductor substrate 10 is of n-type. However, the semiconductor substrate 10 may be of p-type, and n-type impurities may be ion-implanted to form an ion implantation layer after heating.

In each of the embodiments, the semiconductor substrate 10 is made of Ga₂O₃. However, the semiconductor substrate 10 may be made of any suitable material as long as it is made of an oxide semiconductor, and may be made of, for example, a Ga₂O₃-based material such as (AlInGa)₂O₃.

In the second embodiment, the semiconductor device includes a planar gate type MOSFET, but the semiconductor device may have a trench gate type MOSFET formed therein. Furthermore, the semiconductor device may be configured by forming an IGBT having a similar structure in addition to the MOSFET. In the case of an IGBT, the configuration is the same as that of the second embodiment, except that the n+ type substrate 11 in the first embodiment is changed to a p+ type substrate (i.e., collector layer).

What is claimed is:

1. A method of manufacturing a semiconductor device comprising:
preparing a semiconductor substrate made of an oxide semiconductor;
ion-implanting an impurity of a first conductivity type or a second conductivity type on one surface of the semiconductor substrate;
performing an oxygen vacancy compensation within a region of the semiconductor substrate in which an ion implantation layer is to be formed after heating; and
performing a heat treatment to activate the impurity and form the ion implantation layer.

2. The method according to claim 1, wherein the oxygen vacancy compensation includes implanting an oxygen-containing ion that contains oxygen.

3. The method according to claim 2, wherein
the ion-implanting is performed to form an ion implantation layer, before heating, in which the impurity is in an inactive state, and
the heat treatment is performed after the ion-implanting and the oxygen vacancy compensation.

4. The method according to claim 2, wherein the impurity is ion-implanted after performing the oxygen vacancy compensation, at a temperature at which the impurity is activated, thereby simultaneously performing the ion-implanting and the heat treatment.

5. The method according to claim 2, wherein
in the ion-implanting and the oxygen vacancy compensation, the oxygen-containing ion is implanted such that a concentration of oxygen is more than or equal to 0.1 times a concentration of the impurity, in an implantation concentration.

6. The method according to claim 5, wherein
the impurity is ion-implanted and the oxygen-containing ion is ion-implanted, in the ion-implanting and the oxygen vacancy compensation, such that a concentration of oxygen is higher than a concentration of the impurity in an entire region in a depth direction of the semiconductor substrate, in an implantation concentration.

7. The method according to claim 2, wherein
the impurity is ion-implanted and the oxygen-containing ion is ion-implanted, in the ion-implanting and the oxygen vacancy compensation, such that a termination depth of the oxygen-containing ion is deeper than a termination depth of the impurity in a depth direction of the semiconductor substrate, in an implantation concentration.

8. The method according to claim 7, wherein
the impurity is ion-implanted and the oxygen-containing ion is implanted, such that a total amount of oxygen when the oxygen-containing ion is ion-implanted is greater than a total amount of the impurity when the impurity is ion-implanted, in an implantation concentration.

9. The method according to claim 2, wherein at least one ion of Mg, Be, Ca, Zn, N, Ni, Cu, Si, Ge, Sn, C, and Cl is implanted in the ion-implanting.

10. The method according to claim 1, wherein the semiconductor substrate is made of a Ga₂O₃-based material in the preparing of the semiconductor substrate.

11. The method according to claim 10, wherein the semiconductor substrate is made of (AlInGa)₂O₃ as the Ga₂O₃-based material, in the preparing of the semiconductor substrate.
